(19) United States
(12) Patent Application Publication
(10) Pub. No.: US 2016/0169947 A1
(43) Pub. Date: Jun. 16, 2016

(54) Measurement Circuit

(71) Applicant: Dialog Semiconductor (UK) Limited, Reading (GB)

(72) Inventors: Michele De Fazio, Germering (DE); Andrea Acquas, Firenze (IT); Fabio Rigoni, Karlsfeld (DE)

(21) Appl. No.: 14/964,659

(22) Filed: Dec. 10, 2015

(30) Foreign Application Priority Data
Dec. 16, 2014 (DE) 102014226136.8

(51) Int. Cl. G01R 19/30; H03K 5/24; G01R 19/10

(52) U.S. Cl. CPC G01R 19/30; G01R 19/10; H03K 5/24

(57) ABSTRACT

A measurement circuit for providing the maximum and/or minimum voltage of a time-variant electrical input signal is presented. The measurement circuit contains a voltage reference unit to provide voltage reference signals and a comparator unit comprising multiple comparators. Each comparator receiving the electrical input signal at a first comparator input and a different voltage reference signal from the voltage reference unit at its second comparator input. The comparator unit provides comparator output signals based on said electrical input signal and said voltage reference signals. A logic unit receives the comparator output signals and provides a voltage output signal indicative of the maximum and/or minimum voltage of the electrical input signal based on the comparator output signals.

The logic unit provides adaptation information to the voltage reference entity. The is adaptation information is dependent on the comparator output signals. The voltage reference unit adapts the voltage reference signals based on the adaption information.

### TECHNICAL FIELD

The present document relates to measurement circuits. In particular, the present document relates to a measurement circuit providing information regarding the maximum voltage and/or minimum voltage of a time-variant electrical input signal.

### BACKGROUND

Electrical circuits, in particular digital circuits, comprise voltage rails for applying electrical voltage to electrical circuit subunits. The voltage of said voltage rails may vary for different reasons, e.g. due to the electric load of said voltage rail. In order to ensure a reliable operation of the electrical circuits, the voltage of said voltage rails, in particular the supply voltage of the electrical circuit should be in a certain range. So, in order to check the proper function of the electrical circuit, it may be necessary to measure the voltage of at least one electrical input signal. In many cases, the precise value of the input signal is not important and it is sufficient to determine the maximum and/or minimum value of the input signal.

### SUMMARY

There is therefore a need to provide a measurement circuit adapted to provide information regarding the voltage range in which the voltage of an electrical input signal is included. More particularly, there is a need for a measurement circuit that determines the maximum and/or minimum value of a time-variant input signal.

According to an aspect, a measurement circuit for providing information regarding the maximum voltage and/or minimum voltage of an electrical input signal is disclosed. The measurement circuit comprises a voltage reference unit configured to simultaneously provide multiple different voltage reference signals. The voltage reference signals may be distributed, for example, equally distributed across a reference voltage range. The voltage reference unit may be, for example, a multi-DAC (DAC: digital to analog converter). The multi-DAC may be implemented as N different resistor-strings DAC with a dedicated single output multiplexer, or as a single resistor-string DAC with N single output multiplexers attached.

The measurement circuit further includes a comparator unit comprising multiple comparators. In embodiments, at least 3 comparators are provided. Each comparator receives the electrical input signal at a first comparator input and a voltage reference signal from the voltage reference unit at its second comparator input. Each comparator may receive a different voltage reference signal, i.e. the voltage values of the voltage reference signals are different. The comparator unit provides a plurality of comparator output signals, one for each comparator, based on said electrical input signal and said voltage reference signals. More in detail, the comparator unit provides multiple comparator output signals, wherein each comparator output signal indicates whether the voltage of the electrical input signal is above or below the voltage of the respective voltage reference signal. This allows a determination of the maximum and/or minimum value of the input signal.

Finally, the measurement circuit includes a logic unit configured to receive the comparator output signals and further configured to provide a voltage output signal indicative of the maximum voltage and/or minimum voltage of the electrical input signal based on the comparator output signals. In order to dynamically adapt the voltage reference signals to the voltage of the electrical input signal, the logic unit is configured to provide adaptation information to the voltage reference unit. Said adaptation information is dependent on the comparator output signals, i.e. the voltage of the electrical input signal and the voltages of the voltage reference signals. The voltage reference unit is configured to adapt the voltage reference signals provided to the comparator unit based on said adaption information.

The main advantage of the proposed measurement circuit is that information regarding the maximum voltage and/or minimum voltage of a time-variant electrical input signal, in particular an envelope of the voltage of the electrical input signal, can be determined in a very short period of time and said information, respectively, the voltage envelope can be refined iteratively by adapting the voltage reference signals. Said measurement circuit may be included e.g. in an electrical circuit for performing a built-in-self-test routine.

According to embodiments, the measurement circuit operates in measurement cycles wherein in each measurement cycle, voltage reference signals are generated, the input signal compared with the voltage reference signals, and a maximum value and/or a minimum value of the input signal determined based on the comparator outputs. Further, new voltage reference signals are determined to adapt a measurement range in which the voltage reference signals are arranged to increase the measurement accuracy and/or adapt the measurement range to a time varying input signal. The adapted voltage reference signals can then be applied in the next measurement cycle. In such embodiments, the measurement circuit operates typically in a synchronized manner where its components are synchronized and driven by a common clock. The more comparators are provided, the better accuracy of the measurement in one cycle can be obtained, but at the expense of increased hardware resources. If less comparators are employed, measurement accuracy is reduced, which can however be compensated by additional measurement cycles (which need more time for determining the final measurement result). Since only maximum/minimum information about the input signal is generated, the envelope of a high frequency input signal can still be tracked with a relatively low complex circuit.

Each measurement cycle may be sub-divided into different operating phases where the above mentioned steps are performed. A control unit may be provided to control the operations of the components, in particular the steps performed in the operating phases of the measurement circuit. The control unit may be implemented as a processor executing instructions encoded in software, or as a finite state machine.

According to embodiments, the voltage reference unit comprises a plurality of voltage reference generating units, each voltage reference generating unit being adapted to provide a certain voltage reference signal. The voltage reference generating units may include any electric components which can be used to provide a DC-reference voltage. The number of said voltage reference generating units may be greater than the number of comparators included in the comparator unit. In addition, each voltage reference generating unit may provide a different voltage reference signal. Thus, a plurality of voltage reference signals are available for determining the voltage range in which the electrical input signal is included.

According to embodiments, the voltage reference unit is adapted to couple a subset of said voltage reference generating units with the comparator unit based on said adaptation information. For example, the voltage reference unit may comprise a multiplexing unit for coupling a number of selected voltage reference generating units with the comparator unit. By means of said multiplexing unit, a subset of said voltage reference generating units may be selectively coupled with the comparator unit in order to provide appropriate voltage reference signals to the comparator unit.

According to embodiments, the voltage reference unit is adapted to receive adaption information including address information in order to control the multiplexing unit. In other words, the multiplexing unit may receive the adaptation information and couple a subset of voltage reference generating units with the comparator unit based on address information included in the adaptation information. Thereby, a selective provision of voltage reference signals to the comparator unit is possible in order to dynamically adapt the voltage reference signals to the electrical input signal.

According to embodiments, the voltage reference unit comprises a plurality of resistors, each resistor forming a voltage reference generating unit. For example, the voltage reference unit comprises one or more resistor chains, each resistor chain comprising a plurality of resistors being serially coupled. The nodes between two adjacent resistors may be coupled to the input of the multiplexing unit in order to supply the voltage provided at said node as a voltage reference signal to the comparator unit. Thus, a plurality of voltage reference signals is generated by a technically simple and reliable circuit.

According to embodiments, the logic unit is adapted to decode the comparator output signals based on information indicative of the voltage reference signals in order to provide said voltage output signal. Depending on the relation between the electrical input signal and a voltage reference signal, a comparator of the comparator unit provides a high level (e.g. +5V) or a low level (e.g. 0V or −5V).

In other words, the comparator output indicates, in form of a digital signal (e.g. using the above mentioned levels), whether the input signal is larger or smaller than the respective voltage reference signal. Keeping in mind that the comparator unit comprises multiple comparators, the comparator unit provides a digital word which includes multiple digital data values (comparator output signals), each digital data value being associated with a certain comparator, respectively, with a certain voltage reference signal. Based on said digital data, the logic unit decodes the digital word by determining whether the digital data indicate that the voltage of the electrical input signal is greater than the voltage of the voltage reference signal associated with said digital data or not. Thereby, it is possible to determine a voltage range in which the electrical input signal is included. This voltage range may be encoded in many different ways in the voltage output signal and provided to other circuits, e.g. a control circuit that controls operation of a device and which takes action if it is determined that the maximum input voltage exceeds a given threshold (or the minimum input voltage is blow a given threshold).

According to embodiments, the logic unit is adapted to perform a refinement procedure for increasing the accuracy of measurement and the voltage output signal in a next measurement cycle, as was mentioned above. In other words, after determining a coarse voltage range, an adaption signal is provided to the voltage reference unit in order to update the voltage reference signals. Said voltage reference signals may be chosen such that the voltage range covered by said voltage reference signals is reduced, but the voltage of the electrical input signal is still included in said reduced voltage range. Thereby, the voltage output signal is iteratively adapted to the electrical input signal.

According to embodiments, the logic unit is adapted to change a minimum voltage reference signal and/or a maximum voltage reference signal of the multiple different voltage reference signals and/or the voltage difference of at least two consecutive voltage reference signals based on the comparator output signals and/or the present voltage output signal. In addition, the logic unit may receive information regarding the voltage reference signals applied to the comparators of the comparator unit for adapting voltage reference signals. After determining a voltage output signal indicating, for example, a voltage range in which the voltage of the input signal is included or a maximum/minimum value of the input signal, at least a subset of the voltage reference signals may be adapted. For example, the minimum voltage reference signal (i.e. the voltage reference signal with the lowest voltage amongst the voltage reference signals) may be updated to the highest voltage reference signal value associated with a comparator indicating that the input signal is greater than its voltage reference signal. In other words, the minimum voltage reference signal is increased to a value which is slightly below the previously detected voltage of the input signal. In addition, the voltage reference signals between the minimum and maximum voltage reference signals may be adapted such that said voltage reference signals are evenly distributed across the newly determined minimum and maximum reference voltage range, i.e. the voltage steps between two successive voltage reference signals are about identical. It should be noted that the distribution of the voltage reference signals must not be even and the voltage steps identical. Other partitions of the reference voltage range are possible, too.

According to embodiments, the logic unit and/or the comparator unit is adapted to receive a clock signal in order to synchronize the comparator output signals and/or the output of the logic unit with said clock signal. Thereby, the comparator unit provides updated comparator output signals at predefined points of time and/or the logic unit takes over the comparator output signals at predefined points of time. Thus, the voltage output signal is also updated according to said clock signal thereby avoiding that fluctuations of the electrical input signal may falsify the measurement results. The clock signal can be used to synchronize the operation of the components of the measuring circuit, e.g. to control the operation of the voltage reference unit, the comparator unit and/or the logic unit according to the sub-phases of a measurement cycle.

According to embodiments, the comparator unit comprises a plurality of latching comparators being adapted to receive a clock signal in order to synchronize the comparator output signals with said clock signal. Said latching comparators may be adapted to determine and forward the comparator output signals at a certain level or edge of the clock signal, thereby synchronizing the comparator output signals to the clock signal. The comparators may include at least one edge-sensitive or level-sensitive latch.

According to a further aspect, a method for providing information regarding the maximum voltage and/or minimum voltage of a time-variant electrical input signal is disclosed. The method comprises the steps of:
providing multiple different voltage reference signals;
comparing, by means of multiple comparators, an electrical input signal with said multiple different voltage reference signals thereby obtaining comparator output signals;
providing an output signal indicative of the maximum voltage and/or minimum voltage of the electrical input signal based on the comparator output signals; and
adapting the voltage reference signals based on the comparator output signals.

According to embodiments, the lowest voltage reference signal is increased if at least one of said comparator output signals indicates that the maximum voltage of the electrical input signal is above a certain voltage threshold, i.e. a voltage reference signal. Thereby, the lower limit of the reference voltage range is adapted to the present voltage of the input signal and a refinement measuring cycle can follow where the maximum value of the input signal is determined with increased accuracy. By adapting (typically increasing) the lower limit of the reference voltage range, a new and smaller reference voltage range is determined for the following measurement cycle. According to embodiments, the voltage reference signals are adapted such that the voltages of the voltage reference signals are equally distributed across the newly determined reference voltage range. The equal distribution is advantageous because the voltage steps between adjacent voltage reference signals are identical thereby avoiding too large voltage ranges.

In a similar manner, the voltage reference signals and the voltage reference range can be adapted to a time varying input signal. For example, if the comparator output signals indicate that the maximum of the input signal has changed, in particular increased, a new voltage reference range may be determined for the changed input signal. In detail, the lowest voltage reference signal may be increased if at least one of said comparator output signals indicates that the maximum voltage of the electrical input signal is above a certain voltage threshold, e.g. the previous lowest voltage reference signal or the next voltage reference signal.

According to embodiments, the highest voltage reference signal is increased if a change of the comparator output signal of a comparator receiving said maximum voltage reference signal indicates that the voltage of the electrical input signal is greater than the maximum voltage reference signal. Thereby, the upper limit of the reference voltage range can be extended if the voltage of the electrical input signal exceeds the maximum voltage reference signal.

It should be noted that the methods and systems including its preferred embodiments as outlined in the present patent application may be used stand-alone or in combination with the other methods and systems disclosed in this document. Furthermore, all aspects of the methods and systems outlined in the present patent application may be arbitrarily combined. In particular, the features of the claims may be combined with one another in an arbitrary manner. Further, if not explicitly indicated otherwise, embodiments of the invention can be freely combined with each other.

### BRIEF DESCRIPTION OF THE DRAWINGS

The invention is explained below in an exemplary manner with reference to the accompanying drawings, wherein

FIG. 1 illustrates an example schematic block diagram of the measurement circuit;

FIG. 2 shows a schematic flow chart illustrating the steps of a method for providing maximum/minimum voltage information; and

FIG. 3 illustrates an example schematic block diagram of the voltage reference unit.

### DESCRIPTION

The present disclosure is related to the measurement of the peak/valley (maximum/minimum) of a voltage rail inside a circuit over time, and with the testing of such a property inside a circuit. In many applications it can be fundamental to test/measure this property, like for protection of connected devices to power supply rails in a power management application, or for debugging.

The proposed system is designed to generate an envelope of the rail voltage, in order to have an adaptive detection of the voltage peak/valley. An embodiment of the proposed system comprises a multi-DAC comprising a set of N channels with N separated voltage references, a set of N comparators, and a finite state machine (FSM) for providing the measured peak/valley in the necessary form and/or for controlling the N voltage reference channels based on the N comparator outputs. The voltage references may be dynamically changed in value during the voltage peak/valley evaluation.

The multi-DAC generates N different reference voltages distributed inside a MIN/MAX voltage range. The N comparators compare the rail voltage Vᵣₐᵢₗ with the N reference voltages connected from the multi-DAC to the comparators. If the voltage Vᵣₐᵢₗ is higher/lower than a reference voltage, the corresponding comparator provides this information to a logic unit. Based on the combination of the N information coming from the N comparators, the logic unit can calculate the range where the peak/valley was during a certain measurement. The lowest and the highest comparators can detect the min and max voltage in the chosen voltage range.

The FSM allows for operation and control of successive adaptive measurements. A measurement trigger, a measurement stop signal and/or a time-out signal are optionally provided by the FSM to control the measurement. The system can therefore adaptively search for the peak/valley voltage. For example, the FSM can change the multi-DAC reference outputs every time at least one of the N comparators changes state (it should be noted that the FSM can change the range also in case no comparator toggles, which may happen when the reference voltage range Vref is above the peak of the rail voltage Vᵣₐᵢₗ, as explained below). In the subsequent measurement, the FSM may change the range of the multi-DAC reference voltages. The FSM may set the minimum reference to the value of the highest reference at which one of the N comparators has tripped in the previous measurement. If the voltage Vᵣₐᵢₗ goes above/below the maximum peak/valley voltage reference, the system can optionally increase the maximum reference voltage, in order to extend the range on the upper side, in case the highest available voltage reference was not used from the beginning of the measurement.

FIG. 1 shows a schematic structure of a circuit 100 for adaptive detection of maximum voltage and/or minimum voltage information. More specifically, the circuit 100 adaptively provides information regarding a voltage range which includes the voltage of an electrical input signal. Said voltage range information may be used, for example, in built-in-self-test (BIST) applications where an internal logic of a device is used to test one or more functions or blocks of the device. The generated information about a voltage range of an input signal (maximum and/or minimum voltage) can be used by the BIST e.g. to determine proper operating conditions for the device, such as if the input voltage exceeds a predetermined maximum threshold.

The circuit 100 comprises a voltage reference unit 110, a comparator unit 120 and a logic unit 130. The comparator unit 120 comprises multiple comparators 125, each comparator 125 comprising at least a first and a second input and at least one output. The first inputs of said comparators 125 receive a time-variant electrical input signal Vᵣₐᵢₗ. The second inputs of said comparators 125 are coupled with the voltage reference unit 110 for receiving different voltage reference signals. The outputs of said comparators 125 are coupled with inputs of the logic unit 130 in order to provide comparator output signals to the logic unit 130. The logic unit 130 is adapted to provide information regarding the maximum voltage and/or the minimum voltage of the time-variant electrical input signal Vᵣₐᵢₗ at a first output 131 and adaption information at a second output 132. The second output of the logic unit 130 is coupled with the input of the voltage reference unit 110 in order to provide said adaption information to the voltage reference unit 110. The voltage reference unit 110 may be, for example, a digital to analog converter (multi-DAC) providing multiple different voltage reference signals based on the adaption information provided by the logic unit 130.

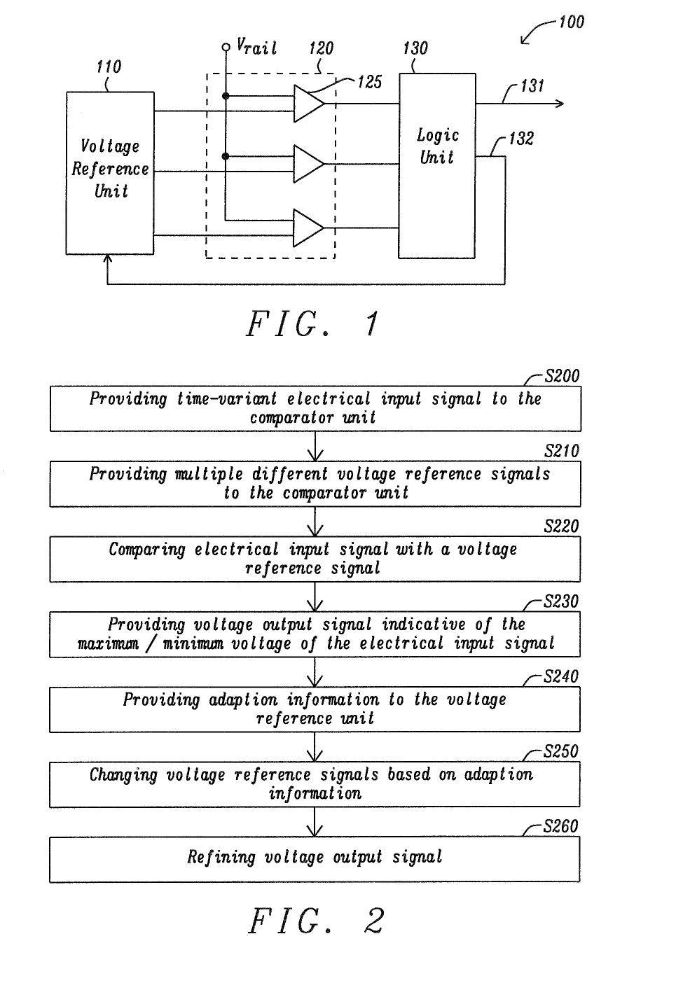

FIG. 2 shows a schematic block diagram of a method for providing information regarding the maximum voltage and/or the minimum voltage of the time-variant electrical input signal. First, a time-variant electrical input signal Vᵣₐᵢₗ is provided to the first inputs of comparators 125 of the comparator unit 120 (S200). In addition, multiple different voltage reference signals are provided to the second inputs of the comparators 125 of the comparator unit 120 (S210), i.e. each comparator 125 receives a different voltage reference signal at its second input. The voltages of said voltage reference signals may be distributed across a reference voltage range. Preferably, the voltages of said voltage reference signals may be equally distributed across said reference voltage range, i.e. the voltage steps between two adjacent voltage reference signals are equal.

The comparators 125 of the comparator unit 120 compare the electrical input signal Vᵣₐᵢₗ with the respective voltage reference signal (S220). The comparators 125 may include operational amplifiers (OPs) which each receive the electrical input signal Vᵣₐᵢₗ and one of the voltage reference signals in order to derive information whether the voltage of the electrical input signal is higher or lower than the voltage of the voltage reference signal. At the output of each comparator 125, a comparator output signal is provided. The comparator output signal may be digital information indicative of the relation (larger/smaller) between the input signal and the respective voltage reference signal of the comparator. Said digital information may be, for example, +5V in case that the electrical input signal Vᵣₐᵢₗ is greater than the voltage reference signal and 0V or −5V in case that the electrical input signal Vᵣₐᵢₗ is lower than the voltage reference signal.

The logic unit 130 receives the comparator output signals and provides a voltage output signal indicative of the maximum voltage and/or minimum voltage of the electrical input signal based on the comparator output signals (S230). Preferably, said voltage output signal may include information in which voltage range the electrical input signal is included, or may directly indicate the maximum or minimum value of the input signal for the last measurement cycle. For example, the maximum of the voltage of the input signal Vᵣₐᵢₗ was 3.8V. The voltage output signal may then indicate a voltage range between 3V and 4V, or a maximum that is larger than 3V. The voltage output signal may be generated based on the comparator output signals and information regarding the voltage reference signals which are applied to the comparators 125 of the comparator unit 120.

For example, a first comparator 125 receives a voltage reference signal VRS=2V, the second comparator 125 receives a voltage reference signal VRS=3V and the third comparator 125 receives a voltage reference signal VRS=4V. The maximum voltage of the electrical input signal Vᵣₐᵢₗ is 3.8V. So, the outputs of the first and second comparators 125 provide comparator output signals indicating that the voltage of the electrical input signal Vᵣₐᵢₗ for that last measuring cycle was greater than the voltage of the voltage reference signals provided to the first and second comparators 125. In contrary thereto, the third comparator 125 provides information that the voltage of the electrical input signal Vᵣₐᵢₗ was lower than the voltage of the voltage reference signal applied to said third comparator 125. So, based on the comparator output signals, the logic unit 130 is able to derive information regarding the voltage range in which the voltage of the electrical input signal Vᵣₐᵢₗ was included.

In order to determine the voltage range more accurately, the logic unit is adapted to trigger a refinement routine by providing adaption information to the voltage reference unit 110 (S240). Said adaption information may include information how the voltage reference signals should be adapted in order to refine the accuracy of the voltage output signal provided by the logic unit 130. In addition, the logic unit 130 may provide the option of successive measurements for performing a build-in-self-test (BIST). A measurement trigger and a measurement stop or a time-out may be optionally provided to perform said BIST. The system can therefore adaptively search for the maximum/minimum voltage.

The logic unit 130 can change the voltage reference signals provided by the voltage reference unit 110 for each measuring cycle or every time at least one of the comparators 125 changed state. In the subsequent measurement, the logic unit 130 may, for example, change the voltage reference range of the multi-DAC reference voltages, and set the minimum voltage reference signal to the value of the voltage reference signal which was applied to the comparator 125 which has changed its state in the previous measurement cycle, thereby indicating that the maximum value of the input signal has changed.

The voltage reference unit 110 may receive the adaption information and change the voltage reference signals based on said adaption information (S250). Based on the changed voltage reference signals, the voltage output signal provided by the logic unit 130 may be refined (S260). Referring to the upper-mentioned example, the adaption information may provide information to the voltage reference unit 110 for increasing the voltages of the voltage reference signals provided to the first and second comparator. Thereby, the range covered by the voltage reference signals is decreased and the accuracy of the voltage output signal is enhanced. For example, the adapted voltages of the voltage reference signals may be 3V, 3.5V and 4V. Thus, the voltage output signal may indicate that the maximum voltage of the electrical input signal Vᵣₐᵢₗ (which is assumed to be still 3.8V) is in the range between 3.5V and 4V. The method may return to step S210 where the adapted voltage reference signals are applied to the comparators of the comparator unit.

As already mentioned above, the logic unit 130 receives the comparator output signals provided by the comparator unit 120. The logic unit may include components, specifically hardware components for decoding the comparator output signals based on the voltage reference signals provided to the comparator unit 120. For example, the logic unit 130 may include a finite state machine being adapted to transform the comparator output signals into a voltage output signal based on the voltage reference signals provided to the comparator unit 120. Based on the comparator output signals provided by said comparators, the logic unit is able to specify the voltage reference signals which form a lower and an upper limit to the maximum of the input signal. Based on the information which voltage reference signal is provided to the respective comparator, the comparator output signals can be transformed into said voltage range output signal.

In order to achieve a reliable measuring result for time varying input signals, the variations in the maximum and minimum values of the input signal should be slower than the measurement time that is necessary to achieve the desired measurement accuracy, i.e. the period of time which is necessary for refining the voltage output signal by using upper-mentioned refinement routine.

Preferably, circuit 100 or sub-units of said circuit 100 may be synchronized by using a clock signal in order to synchronize the components and change the voltage output signal only at certain points of time. For example, the comparator unit 120 and/or the logic unit 130 may receive the clock signal. Preferably, the comparator unit 120 may include latching comparators, said latching comparators comprising an operational amplifier and a latch. Said latch may receive the clock signal and may restrict the change of the comparator output signals to a certain point (edge triggered latch) or period (level triggered latch) of time. In case of a fast varying electrical input signal, the latching comparator may latch on its output transition edge, without waiting for the clock. The transition edge used to trigger latching (positive or negative) depends on what parameter is detected (peak or valley of the input signal). For example, if the peak (maximum) of the input signal is tracked, the latch may be triggered based on the rising edge of the comparator's output. Conversely, if the valley (minimum) of the input signal is tracked, the latch may be triggered based on the falling edge of the comparator's output.

The logic unit 130 may comprise storage means for storing the comparator output signals provided by the comparator unit 120. Said storage may be adapted to store a plurality of comparator output signals which were derived at different points of time in the past. Thereby it is possible to monitor the voltage of the electrical input signal over a certain period of time.

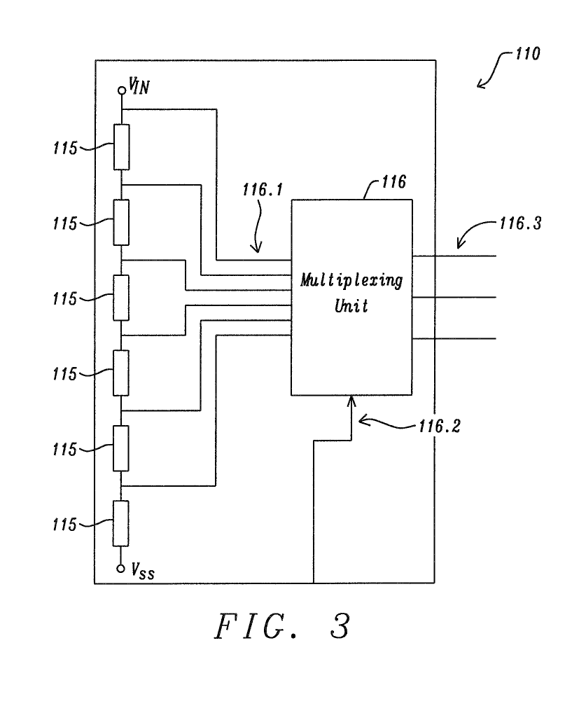

FIG. 3 shows an embodiment of the voltage reference unit 110 in closer detail. The voltage reference unit 110 comprises a plurality of electrical components 115 being serially arranged. Said electrical components may be, for example, resistors, specifically high-impedance resistors. An input voltage Vin is applied to said serial arrangement of said resistors. At the nodes between two adjacent resistors, a voltage value can be tapped, said voltage value depending on the electrical resistors being coupled between the tapping point and the input voltage Vin and the electrical resistors being coupled between the tapping point and Vss (e.g. ground). Preferably, the number of resistors is greater than the number of voltage reference signals applied to the comparator unit 120. For example, the resistors may be chosen such that the voltages provided at the tapping points are equally distributed.

The voltage reference unit 110 further includes a multiplexing unit 116. Said multiplexing unit 116 receives at its inputs 116.1 the voltages of the tapping points, i.e. the inputs 116.1 of the multiplexing unit 116 are connected to the nodes between the electrical components 115. Furthermore, the multiplexing unit 116 may receive the adaption information provided by the logic unit 130 at a second input 116.2. The multiplexing unit 116 may comprise switching means for selectively coupling inputs 116.1 with outputs 116.3 of the multiplexing unit 116. Said switching means may be controlled by the adaption information. For example, the adaption information may be address information, said address information being used for selectively coupling one of the outputs 116.3 with one of said inputs 116.1. Thereby, a desired voltage can be applied to an output 116.3 of the multiplexing unit 116 and during the upper-mentioned refinement routine the voltage reference signal applied to the comparator unit 120 may be changed by triggering an appropriate switching of the multiplexing unit 116.

Returning to the schematic diagram of FIG. 1, the voltage reference unit 110 (multi-DAC) generates N different voltage reference signals which are distributed inside a MIN/MAX voltage range. The number of comparators 125 included in the comparator unit may be N. The N comparators 125 compare the electrical input signal with the N reference voltages provided by the voltage reference unit 110 to the comparator unit 120. If the electrical input signal is higher/lower than the respective voltage reference signal, the corresponding comparator 125 provides comparator information to the logic unit. Based on the combination of the comparator information provided from the N comparators 125, the logic unit can determine the range where the peak/valley is located. The lowest and the highest comparators 125 detect the minimum and maximum voltage in a chosen voltage range.

According to an embodiment, the voltage reference signals may be uniformly distributed across the voltage reference range provided by the voltage reference unit 110. According to another embodiment, the voltage reference signals may be unevenly distributed across said voltage range provided by the voltage reference unit 110. Assuming a uniform distribution, the maximum/minimum voltage will be:

|Vpv|=|Vpv min|*Bcomp1+ΔV*(Bcomp2+. . . BcompN)

where ΔV is the voltage difference between two subsequent voltage reference signals, |Vpvmin| is the voltage of the lowest voltage reference signal, BcompX is the corresponding digital output of a respective comparator X (taking the value 0 or 1) and N is the number of comparators included in the comparator unit 120.

The upper limit of the voltage measurement range |Vpv max| is:

|Vpv max|=|Vpv min|+ΔV*(N−1);

The accuracy of the measure overvoltage Vpvacc can be calculated as:

Vpvacc=(Vpvmax−Vpvmin)/(N−1);

where N is the number of comparators included in the comparator unit 120.

The theoretical maximum accuracy is ΔV. This may be achieved with a number of comparators less than the total number of references from the resistor divider, which is an advantage of the proposed implementation.

If the electrical input signal goes above the maximum voltage reference signal or below the minimum voltage reference signal, the measurement circuit can optionally increase the voltage of the maximum voltage reference signal in order to extend the range on the upper side (assuming that the voltage reference unit is able to provide a greater maximum voltage reference signal).

If the selected references are the tapping points from 0 to N in the Vref generator block, in case all comparators toggle, successive measurements need to be done using references from N+1 to M (with M>N). The procedure may be repeated until M<=X, where X is the maximum number of taps from the reference generator circuit.

Summing up, a measurement circuit 100 for measuring a maximum and/or minimum value of a voltage rail has been proposed. The main advantage of the measurement circuit 100 is that an adaptive measurement of the voltage of an electrical input signal can be performed by a limited number of electrical components thereby enabling a low complexity built-in-self-test (BIST). Due to the adaptive behavior of the measurement circuit 100, information regarding the maximum voltage and/or minimum voltage of a time-variant electrical input signal can be derived with high accuracy.

In the present document, the term “couple” or “coupled” refers to elements being in electrical communication with each other, whether directly connected e.g., via wires, or in some other manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiment outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1) A measurement circuit for providing information regarding the maximum voltage and/or minimum voltage of a time-variant electrical input signal, the measurement circuit comprising:
a voltage reference unit configured to provide multiple different voltage reference signals;
a comparator unit comprising multiple comparators, each comparator receiving the electrical input signal at a first comparator input and a voltage reference signal from the voltage reference unit at a second comparator input, wherein each comparator receives a different voltage reference signal, the comparator unit providing a plurality of comparator output signals based on said electrical input signal and said voltage reference signals; and
a logic unit configured to receive the comparator output signals and configured to provide a voltage output signal indicative of the maximum voltage and/or minimum voltage of the electrical input signal based on the comparator output signals;
wherein the logic unit is configured to provide adaptation information to the voltage reference unit, the adaptation information being dependent on the comparator output signals, and wherein the voltage reference unit is configured to adapt the voltage reference signals based on the adaption information.

2) The measurement circuit according to claim 1, wherein the voltage reference unit comprises a plurality of voltage reference generating units, each voltage reference generating unit being adapted to provide a certain voltage reference signal.

3) The measurement circuit according to claim 2, wherein the voltage reference unit is adapted to selectively couple a subset of said voltage reference generating units with the comparator unit based on said adaptation information.

4) The measurement circuit according to claim 2, wherein the voltage reference unit comprises a multiplexing unit for selectively coupling a subset of said voltage reference generating units with the comparator unit based on said adaptation information.

5) The measurement circuit according to claim 4, wherein the voltage reference unit is adapted to receive adaption information including address information in order to control the multiplexing unit.

6) The measurement circuit according to claim 1, wherein the voltage reference unit comprises a plurality of resistors, the voltage reference signals generated by the resistors.

7) The measurement circuit according to claim 1, wherein the logic unit is adapted to decode the comparator output signals based on information indicative of the generated voltage reference signals in order to provide said voltage output signal.

8) The measurement circuit according to claim 1, wherein the logic unit is adapted to perform a refinement procedure for increasing the accuracy of the measured information regarding the maximum and/or minimum value of the input signal.

9) The measurement circuit according to claim 8, wherein the logic unit is adapted to change a minimum voltage reference signal and/or a maximum voltage reference signal and/or the voltage difference of at least two consecutive voltage reference signals based on the comparator output signals and/or the voltage output signal.

10) The measurement circuit according to claim 1, wherein the logic unit and/or the comparator unit are adapted to receive a clock signal in order to synchronize the comparator output signals and/or the output of the logic unit with said clock signal.

11) The measurement circuit according to claim 1, wherein the comparator unit comprises a plurality of latching comparators being adapted to receive a clock signal in order to synchronize the comparator output signals with said clock signal.

12) A method for providing information regarding the maximum voltage and/or minimum voltage of an time-variant electrical input signal, the method comprising the steps of:
providing multiple different voltage reference signals;
comparing, by means of multiple comparators, an electrical input signal with said multiple different voltage reference signals thereby obtaining comparator output signals;
providing an output signal indicative of the maximum voltage and/or minimum voltage of the electrical input signal based on the comparator output signals; and
adapting the voltage reference signals based on the comparator output signals.

13) The method according to claim 12, wherein the lowest generated voltage reference signal is increased if at least one of said comparator output signals indicates that the maximum voltage of the electrical input signal is above the lowest voltage reference signal.

14) The method according to claim 12, wherein the voltage reference signals are adapted such that the voltages of the voltage reference signals are equally distributed across the voltage range covered by said voltage reference signals.

15) The method according to claim 12, wherein the highest voltage reference signal is increased if the comparator output signal of the comparator receiving said maximum voltage reference signal indicates that the maximum voltage of the electrical input signal is greater than the maximum voltage reference signal.

16) The method according to claim 12, further comprising the step of:
providing in the voltage reference unit a plurality of voltage reference generating units, each voltage reference generating unit being adapted to provide a certain voltage reference signal.

17) The method according to claim 16, further comprising the step of:
adapting the voltage reference unit to selectively couple a subset of said voltage reference generating units with the comparator unit based on said adaptation information.

18) The method according to claim 16, further comprising the step of:
providing in the voltage reference unit a multiplexing unit for selectively coupling a subset of said voltage reference generating units with the comparator unit based on said adaptation information.

19) The method according to claim 18, further comprising the step of:
adapting the voltage reference unit to receive adaption information including address information in order to control the multiplexing unit.

20) The method according to claim 12, further comprising the step of:
providing in the voltage reference unit a plurality of resistors, the voltage reference signals generated by the resistors.

21) The method according to claim 12, further comprising the step of:
adapting the logic unit to decode the comparator output signals based on information indicative of the generated voltage reference signals in order to provide said voltage output signal.

22) The method according to claim 12, further comprising the step of:
adapting the logic unit to perform a refinement procedure for increasing the accuracy of the measured information regarding the maximum and/or minimum value of the input signal.

23) The method according to claim 22, further comprising the step of:
adapting the logic unit to change a minimum voltage reference signal and/or a maximum voltage reference signal and/or the voltage difference of at least two consecutive voltage reference signals based on the comparator output signals and/or the voltage output signal.

24) The method according to claim 12, further comprising the step of:
adapting the logic unit and/or the comparator unit to receive a clock signal in order to synchronize the comparator output signals and/or the output of the logic unit with said clock signal.

25) The method according to claim 12, further comprising the steps of:
providing in the comparator unit a plurality of latching comparators being adapted to receive a clock signal in order to synchronize the comparator output signals with said clock signal.
